(19) United States
(12) Patent Application Publication
(10) Pub. No.: US 2025/0341576 A1
(43) Pub. Date: Nov. 6, 2025

(54) WIRELESS PROVISION OF INFORMATION FROM SWITCH FUNCTION TESTS

(71) Applicant: Siemens Aktiengesellschaft, München (DE)

(72) Inventors: Maik Gruhle, Nürnberg (DE); Eduard Bechtold, Poppenricht (DE); Michael Decker, Nürnberg (DE); Gerd Müller, Falkensee (DE)

(21) Appl. No.: 18/870,772

(22) PCT Filed: May 23, 2023
(86) PCT No.: PCT/EP2023/063773

§ 371 Date: Dec. 2, 2024

(30) Foreign Application Priority Data
Jun. 2, 2022 (DE) 10 2022 205 652.3

(51) Int. Cl. G01R 31/333; G08C 17/02

(52) U.S. Cl. CPC G01R 31/3333; G08C 17/02

(57) ABSTRACT

A switch arrangement contains a switch and is configured to perform a test directed to an aspect of the functionality of the switch, to store data relating to the performed test in a local memory apparatus and to respond to a request for data pertaining to one or more performed tests that is transmitted by use of a first protocol for wireless communication by transferring data pertaining to performed tests, which data are stored in the memory apparatus, by one or more messages to a receiver specified by the request. The test permits improved and more efficient analysis of the behavior of switches.

The invention relates to a switch arrangement, a system and a method for the wireless provision of information from switch function tests.

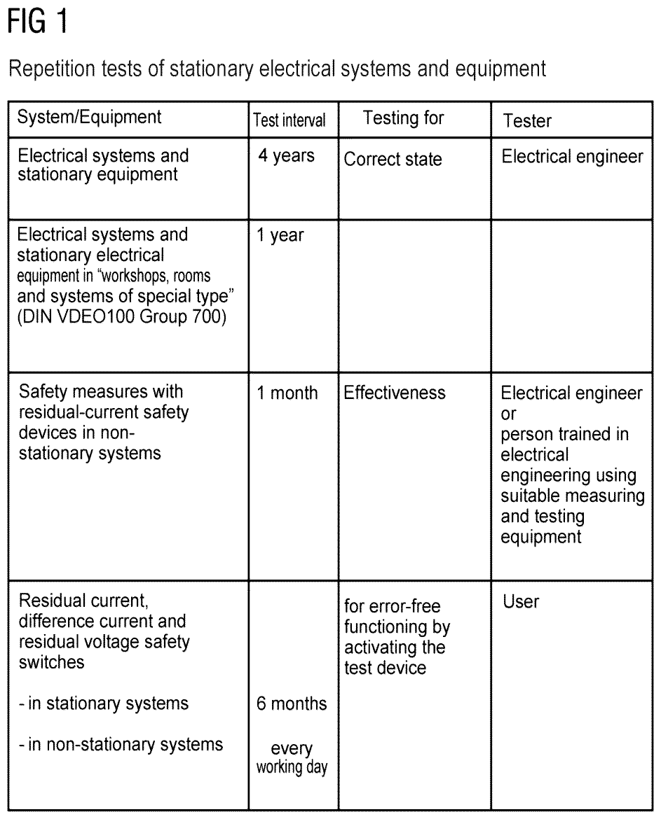

In many cases, regular tests are planned for electrical systems to ensure their functionality. This applies in particular if circuit breakers are installed in the systems. FIG. 1 shows an exemplary table for test requirements for stationary electrical systems and equipment.

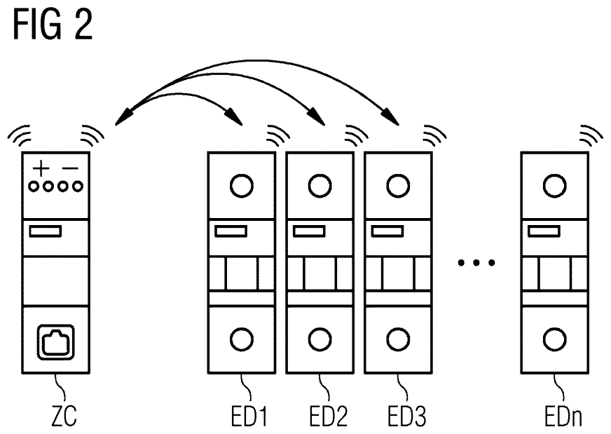

Tests (e.g. residual current and insulation resistance measurements) are increasingly being initiated wirelessly. FIG. 2 shows how multiple low-voltage elements (e.g. low-voltage protective devices or breakers) ED1, ED2, ED3 and EDn (ED: end device) are wirelessly connected to a data collector or data concentrator ZC (ZC stands for Zigbee coordinator). Communication takes place via the Zigbee protocol. Data for applications can then be sent directly or indirectly to the cloud via the data collector ZC. The data concentrator ZC allows the provision of data in the cloud to be flexibly designed, e.g. with regard to settings, data adaptations and transmission options.

Typical low-voltage protective devices are residual current circuit breakers (also referred to as RCDs or residual current breakers), miniature circuit breakers (also referred to as MCBs) and fire safety switches (also referred to as AFDD or arc fault detection devices). Switches of these types may also not be capable of communication themselves. The communication capability is then realized via mechanical coupling to a communication module (Remote Control Auxiliary (RCA)) device. Such a module is described, for example, in DE 202021000293 U1.

The object of the invention is to achieve an improved analysis of the behavior of switches.

This object is achieved by a switch arrangement as claimed in claim 1, a system as claimed in claim 5, comprising a switch arrangement according to the invention and a terminal device, and/or by a method as claimed in claim 10.

According to the invention, a switch arrangement comprising a switch is proposed. The switch arrangement may be identical to the switch. Alternatively, it is possible, for example, that the switch arrangement consists of a combination of a switch and an add-on module, in particular if the switch itself is not configured for wireless communication. Such an add-on module may also be required for conducting tests of the switch if the switch is not configured for self-testing. Such an add-on module does not need to be permanently coupled to the switch, but can also be attached to the switch only for a designated test period. The switch itself can be, for example, a low-voltage protection switch or a low-voltage circuit breaker.

The switch arrangement according to the invention is designed to conduct a test directed to one aspect of the functionality of the switch and to store data related to the test conducted in a local memory device (e.g. ring buffer). In the case of a combination of a switch and add-on module, this memory device can be arranged in the switch or in the add-on module. The switch arrangement is also configured to respond to a request, transmitted by means of a first wireless communication protocol, for data stored in the memory device relating to one or more conducted tests by transferring data relating to conducted tests by means of one or more messages to a recipient specified by the request.

For example, the first wireless communication protocol is the Zigbee protocol. Then the request for data relating to one or more conducted tests and the one or more messages for the transfer of stored data relating to conducted tests can take place by means of (i.e. to a certain extent proprietary) Zigbee commands created for this purpose. For example, a REQUEST_LOG command is provided for the request and a RESPONSE_LOG for the transfer of data by the memory device. It may be necessary to send a plurality of RESPONSE_LOG messages to transfer all requested data. When transferring LOG data using multiple Zigbee messages, it may be useful to divide the data relating to conducted tests required as part of a request into multiple messages using Zigbee fragmentation before transmission to the recipient.

The invention thus enables an efficient and user-friendly provision of data logged in the course of switch tests (LOG data).

The subject matter of the invention also comprises a system having a switch arrangement according to the invention and a terminal device. The terminal device comprises a software app (i.e. an application software or a computer program that provides functions for the user of the terminal device to which the user has access), which is configured to obtain the data relating to one or more conducted tests and to enable the data to be exported in a file from the app. This app can be configured to send, by means of a second wireless communication protocol, a request for data stored in the storage device relating to one or more conducted tests and to receive one or more messages containing requested data transferred by means of the second protocol. In particular, the following two configurations can occur:
a) The first and second protocols can be identical (e.g. Bluetooth or TCP). The app of the terminal device is then configured to send, by means of this wireless communication protocol, a request for data stored in the memory device relating to one or more conducted tests directly to the switch arrangement and to receive one or more transferred messages containing requested data directly from the switch arrangement. “Directly” implies here that the messages are addressed accordingly. This configuration is preferably used for larger switches, e.g. circuit breakers for low-voltage and medium-voltage technology.
b) The system comprises a data collector. This is configured for receiving a request for data stored in the memory device relating to one or more conducted tests, sent by means of the second wireless communication protocol (e.g. TCP or Bluetooth) to the switch arrangement, from the app (the request may be formed by one or more Modbus commands that can be interpreted by the switch arrangement) and to send one or more messages containing requested data the switch arrangement to the terminal device by means of the second wireless communication protocol. In addition, the data collector is configured to adapt a request, sent by means of the second wireless communication protocol, for data stored in the memory device relating to one or more conducted tests to the switch arrangement for transfer by means of the first protocol and to transfer said request to the switch arrangement (i.e. the data collector functions as a protocol converter). Finally, the data collector is also configured to receive one or more messages containing requested data for the switch logbook entries, transmitted by means of the first protocol, to adapt the one or more messages for transfer by means of the second protocol and to transmit them by means of the second protocol to a terminal device (e.g. a mobile phone) (in the course of the protocol conversion, messages received may be combined for more efficient transmission to the terminal device).

The invention also relates to a method for wireless provision of information from switch function tests. This includes conducting a test directed to one aspect of the functionality of the switch, storing data related to the conducted test in a local memory device of a switch device, and sending one or more messages, wherein the sending is triggered by a request sent by means of a first wireless communication protocol for data stored in the memory device and the data is sent to a recipient specified by the request. The request for data relating to one or more conducted tests and the sending or transfer of one or more messages containing stored data relating to conducted tests can take place by means of Zigbee commands created for this purpose. In this case, the data relating to conducted tests, requested as part of a requirement, can be divided over a plurality of messages by Zigbee fragmentation before transfer to the recipient.

The invention is explained in further detail below based on exemplary embodiments with the aid of drawings. In the drawing:

FIG. 1: shows an exemplary table for test requirements for stationary electrical systems and equipment,

FIG. 2: shows a data collector and low-voltage protective devices which are connected to each other wirelessly,

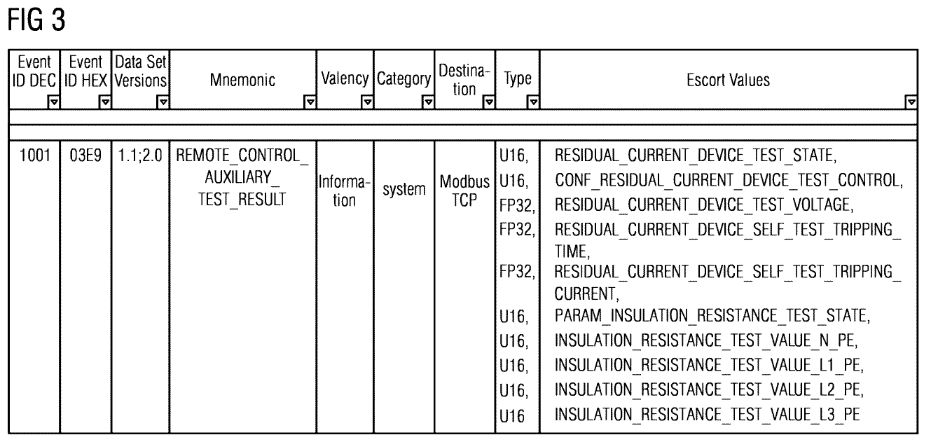

FIG. 3: shows a Modbus map for a log format of a switch test,

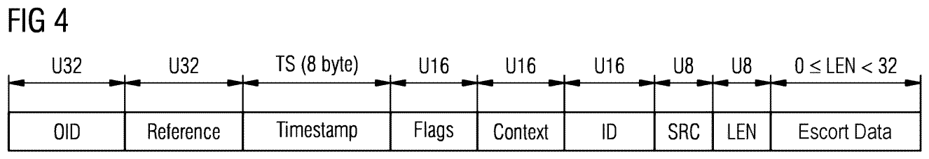

FIG. 4: shows a data format for the transfer of log data from a switch test,

FIG. 5: shows ZigBee commands “REQUEST_LOG” and “RESPONSE_LOG” for querying or transferring log data of a switch test,

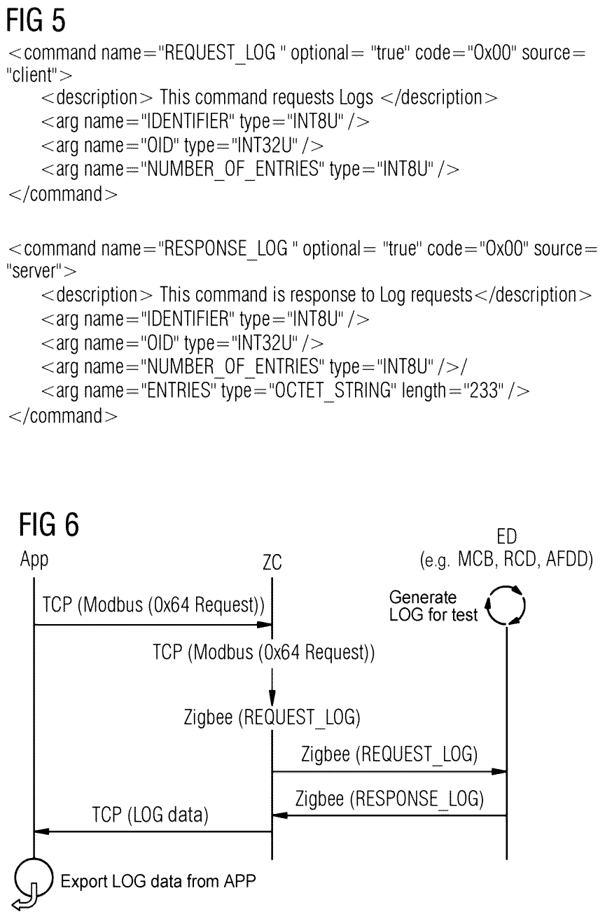

FIG. 6: shows a flowchart for a first example of a method according to the invention (with data collector), and

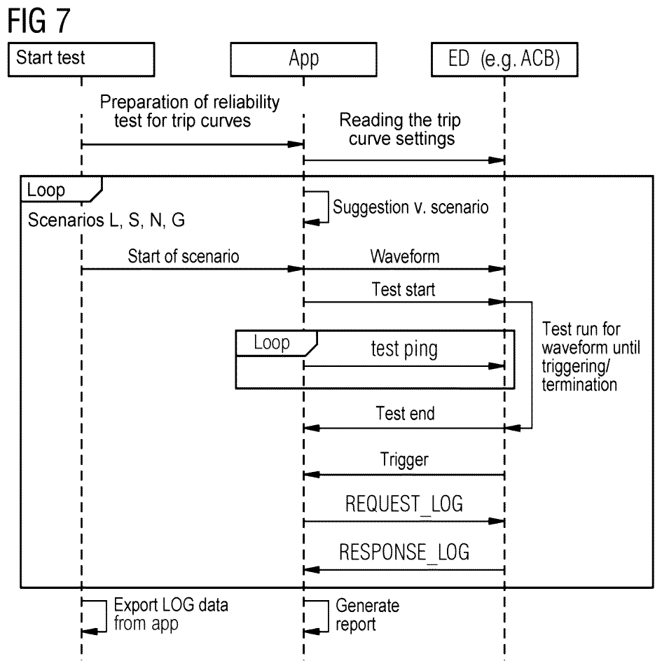

FIG. 7: shows a flowchart for a second example of a method according to the invention (without data collector).

Tests (e.g. residual current and insulation resistance measurements) are conducted and automatically logged. The tests can be carried out largely automatically and, for example, regularly at specified time intervals. According to the invention, a log entry with information about the respective test is automatically generated for each test. A separate log file with the corresponding log entry can be generated for each test. Alternatively, there is a single log file for all tests, or at least for all tests of one type, in which the test results are written in sequence. For example, a persistent or non-volatile ring buffer is provided for the log information.

By means of firmware, test results (e.g. from residual current and insulation resistance measurements) are stored persistently in a ring buffer. An automated test on a Zigbee end device is configured by way of Modbus parameters and started using a Modbus command. Alternatively, a test can also be started manually or a single test can be started via a Modbus command. After a test has completed, a log entry is then automatically created. The log format for tests is specified separately in a so-called Modbus map (data point list). A Modbus map is a feature of the Modbus protocol. This is a list for a slave device (here: ZigBee end device) that describes
what data is involved (e.g. switch test),
where the data is stored (e.g. data addresses) and
how the data is stored (e.g. data type, byte and word arrangement).

FIG. 3 shows an example of a Modbus map for the log format for tests.

This includes the following fields:
Event ID DEC: Identifier for the respective test
   (decimal value)
Event ID HEX: Identifier for the respective test
   (hexadecimal value)
Data Set Versions: supported software versions
Mnemonic: Text explanation for log information
Valency: Classification of the entry
   (information, warning, alarm)
Category: Category of the entry (system, operator)
Destination: Transmission protocol
Type: Attribute type of the test-related data
Escort Values: test-related data

In FIG. 3, the following entries are assigned to the individual fields:
Event ID DEC: 1001
Event ID HEX: 03E9
Data Set Versions: 1.1; 2.0
Mnemonic: REMOTE_CONTROL_AUXILIARY_TEST_RESULT
Valency: Information
Category: system
Destination: ModbusTCP
Type: U16 or FP32
Escort Values:
RESIDUAL_CURRENT_DEVICE_TEST_STATE
CONF_RESIDUAL_CURRENT_DEVICE_TEST_CONTROL
RESIDUAL_CURRENT_DEVICE_TEST_VOLTAGE
RESIDUAL_CURRENT_DEVICE_SELF_TEST_TRIPPING_TIME
RESIDUAL_CURRENT_DEVICE_SELF_TEST_TRIPPING_CURRENT
PARAM INSULATION_RESISTANCE_TEST STATE
INSULATION_RESISTANCE_TEST_VALUE N PE
INSULATION_RESISTANCE_TEST_VALUE_L1_PE
INSULATION_RESISTANCE_TEST_VALUE_L2_PE
INSULATION_RESISTANCE_TEST_VALUE_L3_PE

The “Escort Values” correspond to test-related information determined during a test:
RESIDUAL_CURRENT_DEVICE_TEST_STATE: Difference current test result (test passed or not, due to different fault causes)
CONF_RESIDUAL_CURRENT_DEVICE_TEST_CONTROL: Test configuration information (tripping current and insulation resistance)
RESIDUAL_CURRENT_DEVICE_TEST_VOLTAGE: Test voltage
RESIDUAL_CURRENT_DEVICE_SELF_TEST_TRIPPING_TIME: Tripping time
RESIDUAL_CURRENT_DEVICE_SELF_TEST_TRIPPING_CURRENT: Tripping current (difference current)
PARAM_INSULATION_RESISTANCE_TEST_STATE: Insulation test measurement result
INSULATION_RESISTANCE_TEST_VALUE_N_PE: Insulation resistance N to PE
INSULATION_RESISTANCE_TEST_VALUE_L1_PE: Insulation resistance L1 to PE
INSULATION_RESISTANCE_TEST_VALUE_L2_PE: Insulation resistance L2 to PE
INSULATION_RESISTANCE_TEST_VALUE_L3_PE: Insulation resistance L3 TO PE

Here, L1-L3 are the phase conductors, N is the neutral conductor and PE is the protective conductor.

The test result is transmitted via Zigbee to a terminal device (e.g. mobile phone) and displayed via an app. Provided by file export from the app for proof of testing.

FIG. 4 shows the log format specified for the test logs, by means of which log information can be transmitted as datagrams or data frames.

Each test log entry has a continuous OID (Object ID), a timestamp and an escort data area of flexible length (up to a maximum of 32 bytes). Via the escort data it is possible to store details of the test result in the log, for example test status, fault current, insulation measured values. A list of all fields of the test log of FIG. 4 is given below.
OID (Object ID): Identification number of the entry
Reference: Reference to another entry
Timestamp: Timestamp
Flags: Flag register contains valency, category, etc.
Context: System context (0x0001) for wireless system
ID: EVENT ID (1001 for REMOTE_CONTROL_AUXILIARY_TEST_RESULT)
SRC: Source device e.g. 7 for RCA device.
LEN: Size of the “Escort data” field (number of bits)
Escort data: test-related data

In the information given above the fields, “U” stands for “unsigned integer” and the number after it (e.g. 8, 16, 32) stands for the width in bits of the respective field.

Using self-created Zigbee commands or instructions, the log information can be transmitted via Zigbee. For this purpose, individually specified Zigbee commands “REQUEST_LOG” for requesting log information for a test and “RESPONSE_LOG” for transferring the requested information are shown in FIG. 5.

FIG. 6 illustrates a query for log information with the aid of these commands. The starting point here is an app (e.g. the PowerConfig app from the Siemens company), which exchanges information via a data collector ZC, which, as shown in FIG. 2, uses the Zigbee protocol to exchange information with Zigbee end devices ED (e.g. for communication with Zigbee-enhanced circuit breakers).

For example, the data collector ZC can be the Siemens product marketed under the name “Powercenter 1000”.

In a first step, log information is generated in the course of a test according to the description in FIG. 4. The test can be initiated locally (e.g. by pressing a button) or remotely.

Using Modbus TCP or Modbus RTU over BLE Gatt (Bluetooth Low Energy) and a proprietary 0x64 Request Log command, the app, or the hardware on which the app runs, requests log information related to tests from Zigbee end devices on the data collector DC. The data collector translates the Modbus command into the “REQUEST_LOG” Zigbee command and sends it accordingly to the Zigbee end device ED selected by the app. The Zigbee end device ED processes the REQUEST_LOG Zigbee command and responds with the RESPONSE_LOG command and the same Zigbee sequence number (Sequence Number) and the maximum possible log entries “ENTRIES”. Using Zigbee fragmentation, multiple log entries can thus be transmitted at once, despite a very limited Zigbee packet length. By using a fragmented RESPONSE_LOG response, for example, 50 log entries can be transmitted in 5 seconds (with an average of 6 entries per RESPONSE_LOG) instead of 30 seconds (with one RESPONSE_LOG response per entry). The result of the RESPONSE_LOG command can be read or queried in the data collector ZC via a specially defined data point after successful processing. The data transmitted by means of multiple RESPONSE_LOG commands can be combined by the data collector ZC to form a data field for further transmission. The data received by means of multiple RESPONSE_LOG commands is then transferred together from the data collector ZC to the app (message TCP (LOG data) in FIG. 6). These data can also relate to multiple tests. The LOG data can be assigned to individual tests via the OID (Object ID) (e.g. the incrementing of the OID signals that the subsequent data must be assigned to a new test). The app is extended to include a test protocol export function for storing a test protocol. This includes reading out the log entries of tests, as well as preparing and formatting in PDF and CSV format. With the file export option, proof of conducting the test is provided with the associated result.

FIG. 7 shows a further exemplary embodiment of the subject matter of the invention. In contrast to FIG. 6, which shows the application of the invention to a circuit breaker (e.g. MCB, RCD or AFDD) which exchanges data with an app by means of a data collector ZC (see also FIG. 2), the configuration for a low-voltage circuit breaker is shown in FIG. 7 by way of example. Low-voltage circuit breaker types are, for example, open circuit breakers (also referred to as ACB or air isolated circuit breakers) and closed circuit breakers (also referred to as MCCBs or molded case circuit breakers). These switches often communicate with an end device ED directly, rather than via a data collector ZC. Such a configuration is shown in FIG. 7. A test is initiated, e.g. by maintenance personnel. This might be, for example, a reliability test for trip curves (circuit breakers typically trip according to a tripping configuration, which is usually realized as a trip curve and takes into account both the current level and its duration). Trip curve settings for the test are communicated to the circuit breaker (here: ACB) via an app (e.g. the PowerConfig app from Siemens). A test scenario is then selected (optionally, proposed by the app) and started. In line with the scenario a waveform (typically current) is specified. On this basis, the ACB then starts the test. During the test, ping messages can be used to verify that there are no communication faults between the app and the ACB. The test on the ACB is conducted until a completion criterion is met. This is either the triggering of the switch (tripping) or the expiry of a timer (if the switch does not trip). The end of the test and, if appropriate, the fact that the switch has tripped are communicated to the app one consecutively. During the test-in a similar way to that described above-LOG information about the test is stored and can also be queried by the app with the commands REQUEST_LOG or RESPONSE_LOG. For the transmission, the protocol used is, for example, TCP or Bluetooth. Similar to FIG. 6, LOG information can be exported from the app. For example, this can include a report generated by the app, which may be stored in the cloud by the app.

The invention has been explained in more detail above by way of exemplary embodiments. These are only illustrative. The invention can be used throughout the entire field of low-voltage technology and beyond. For example, the invention can also be used for tests of low-voltage switches which are used for low-voltage control of a medium-voltage circuit breaker.

1-12. (canceled)

13. A switch arrangement, comprising:
a local memory device;
a switch, the switch arrangement is configured to:
carry out a test aimed at one aspect of a functionality of said switch;
store data related to the test conducted in said local memory device; and
respond to a request, transmitted by means of a first wireless communication protocol, for the data stored in said local memory device relating to at least one conducted test by transferring the data relating to one or more conducted tests by means of at least one message to a recipient specified by the request.

14. The switch arrangement according to claim 13, wherein the first wireless communication protocol is a Zigbee protocol.

15. The switch arrangement according to claim 14, wherein the request for the data relating to the one or more conducted tests and the at least one message for a transfer of the data relating to the conducted tests takes place by means of Zigbee commands.

16. The switch arrangement according to claim 15, wherein the data relating to the conducted tests, required as part of the request, is divided over a plurality of messages by Zigbee fragmentation for transfer to the recipient.

17. The switch arrangement according to claim 13, wherein said switch is a circuit breaker.

18. A system, comprising:
a switch arrangement having a switch and a local memory device, said switch arrangement configured to:
carry out a test aimed at one aspect of a functionality of said switch;
store data related to a conducted test in said local memory device; and
respond to a request, transmitted by means of a first wireless communication protocol, for the data stored in said local memory device relating to one or more conducted tests by transferring the data relating to the conducted tests by means of at least one message to a recipient specified by the request; and
a terminal device having a software app configured to receive the data relating to the one or more conducted tests, and to export the data from said software app in a file.

19. The system according to claim 18, wherein said software app of said terminal device is configured to send, by means of a second wireless communication protocol, the request for the data stored in said local memory device relating to the one or more conducted tests and to receive the at least one message containing the data requested transferred by means of the second wireless communication protocol.

20. The system according to claim 19, wherein:
said first wireless communication protocol and said second wireless communication protocol are identical; and
said software app of said terminal device is configured to send, by means of one of the first and second wireless communication protocols, the request for the data stored in said local memory device relating to the one or more conducted tests, to said switch arrangement and to receive the at least one message containing the data requested from said switch arrangement.

21. The system according to claim 19, further comprising a data collector configured to:
receive the request from the software app, sent by means of the second wireless communication protocol, for the data relating to the one or more conducted tests conducted by said switch arrangement;
send, by means of the second wireless communication protocol, the at least one message containing the data requested from said switch arrangement to said terminal device;
adapt the request, sent by means of the second wireless communication protocol, for the data stored in said local memory device relating to the one or more conducted tests to said switch arrangement for transfer by means of the first wireless communication protocol and to transfer the request to said switch arrangement; and
receive the at least one message containing the data requested transferred by means of the first wireless communication protocol from said switch arrangement, and to adapt the at least one message for transfer by means of the second wireless communication protocol and to send the at least one message by means of the second wireless communication protocol to said terminal device.

22. The system according to claim 21, where the second wireless communication protocol is a transmission control protocol (TCP) or Bluetooth.

23. The system according to claim 18, wherein said switch is a circuit breaker.

24. The system according to claim 20, wherein the system is configured for power circuit breakers.

25. A method for wireless provision of information from switch function tests, which comprises the steps of:
conducting a test aimed at one aspect of a functionality of a switch;
storing data relating to the test conducted in a local memory device for the switch;
receiving a request for the data relating to one or more tests conducted, sent by means of a first wireless communication protocol; and
sending at least one message containing the data relating to the tests conducted to a recipient specified by the request.

26. The method according to claim 25, wherein the request for the data relating to the one or more conducted tests and the sending of the at least one message containing the data relating to the conducted tests take place by means of Zigbee commands.

27. The method according to claim 25, wherein the data relating to the conducted tests, required as part of the request, is divided over a plurality of messages by Zigbee fragmentation for transfer to the recipient.
